(19) United States
(12) Patent Application Publication
(10) Pub. No.: US 2011/0180120 A1
(43) Pub. Date: Jul. 28, 2011

(54) Thermomagnetic Generator

(75) Inventors: Bruce Ringsby Olmstead, Pretoria (ZA); Ingo Bayer, London (GB)

(73) Assignee: BHP Billiton Aluminium Technologies Limited, Jersey (GB)

(21) Appl. No.: 13/062,418

(22) PCT Filed: Sep. 8, 2009
(86) PCT No.: PCT/EP09/61639

§ 371 Date: Apr. 11, 2011

(30) Foreign Application Priority Data
Sep. 8, 2008 (AU) 2008904667
Nov. 12, 2008 (AU) 2008905854

(51) Int. Cl. H01L 35/30

(52) U.S. Cl. 136/205

(57) ABSTRACT

An apparatus for the conversion of thermal energy from a surface (20) of a pyrometallurgical vessel associated with a magnetic field to electrical energy, the device comprising a thermoelectric device having at least one thermoelectric element (60) capable of converting a thermal energy differential into electrical energy whereby appropriate alignment in the magnetic field increases the ability of the thermoelectric device to generate electrical energy; and a support structure (50) engagable with the pyrometallugical vessel, the support structure being able to support the thermoelectric device in a fixed position relative to the pyrometallurgical vessel and in the associated magnetic field so that a temperature differential exists between a first side (30) and a second side (40) of the thermoelectric device. In a preferred form the thermoelectric device is aligned in the magnetic field associated with the pyrometallurgical vessel to generate greater electrical energy from the device than would be generated in the absence of the magnetic field.

### FIELD OF THE INVENTION

This invention relates to a thermomagnetic device for extracting usable energy from waste heat from industrial metallurgical processes.

### BACKGROUND OF THE INVENTION

There is a class of thermoelectric materials in which the thermoelectric effect is increased when the material is suitably oriented in a magnetic field. Prior art seeking to utilise this increased efficiency of heat conversion has relied on a placing the thermoelectric material into a magnetic field provided by one or more permanent magnets located adjacent to the material.

In the context of the invention, pyrometallurgy consists of the thermal treatment of minerals, metallurgical ores and concentrates to bring about physical and chemical transformations in the materials to enable recovery of valuable metals. Pyrometallurgical processes typically include one or more of the following processes:
drying
calcining
roasting
fuming
smelting
refining

While the invention will be described with reference to vessels for the reduction of alumina to aluminium, it is equally applicable to any structures used in pyrometallurgical treatment, refining, extraction or processing of ores, metals and their various compounds. Typically, such processes occur at temperatures in excess of 100° C. This invention specifically is applied to any pyrometallurgical processing structure which generates magnetic fields during its operation and this description of the invention is thus not intended to be limited solely to its use in the aluminium industry. Where suitable magnetic fields exist, this invention can also be applied to energy conversion from hot off-gases for pyrometallurgical processes.

By their nature, aluminium refining and smelting processes have significant power requirements. For instance, during reduction of aluminium oxide (alumina) to form aluminium in electrolytic cells only about 30% of the total power consumed is actually used by the reduction process with a substantial proportion of the remainder being lost as diffuse heat. A modern aluminium smelting operation may, through the necessary heating of the reduction environment, in turn lose in excess of 600 MW of energy by natural heat fluxes through the sides and top of the reduction vessels.

Electrolytic cells for the production of aluminium comprise an electrolytic tank having at least one cathode and at least one anode. The electrolytic tank consists of an outer steel shell having carbon cathode blocks sitting on top of a layer of insulation and refractory material along the bottom of the tank. While the precise structure of the side walls varies, a lining comprising a combination of carbon blocks and refractory material is provided against the steel shell. During the electrolytic process, a large electric current is passed from the anode to the cathode (creating a large magnetic field). Aluminium oxide is dissolved in a cryolite bath present in the tank. The operating temperature of the cryolite bath is normally in the range of 930° C. to about 970° C. Some of this energy is lost as diffuse heat by natural heat fluxes through the side walls of the tank.

Apart from this heat loss leading to power inefficiency, the heat transfer and subsequent cooling of the cryolite bath at the side walls affects the formation of a layer of ‘frozen’ cryolite bath on the inside of the side walls of the electrolytic tank. The thickness of this layer/crust/ledge may vary during operation of the cell, with that thickness of frozen bath depending for instance on cryolite bath temperature (which is responsive to current flow between the anode and cathode) and heat removal from the outside of the side walls of the vessel. If the crust becomes too thick it will affect the operation of the cell as the crust will grow on the cathode and disturb the cathodic current distribution affecting the magnetic field. If the crust becomes too thin or is absent in some places, the cryolite bath may attack the side wall lining and ultimately result in its failure (necessitating its replacement to avoid damage to the steel shell and possible spillage of cryolite bath from the tank). Thus, controlled ledge formation is essential for good pot operation and long lifetime of the refractory lining within the cell. It follows therefore that controlling the flow of heat from the bath through the side wall lining is essential for controlled ledge formation within the cell.

Accordingly, the present invention provides a means for harvesting heat energy lost from a surface of a processing structure, such as an electrolysis cell, to enhance its electrical efficiency and, in the case of an electrolysis cell, to provide an improved thermodynamic environment on the inside of the side walls such that crust formation is better controlled.

Reference to any prior art in the specification is not, and should not be taken as, an acknowledgment or any form of suggestion that this prior art forms part of the common general knowledge in Australia or any other jurisdiction or that this prior art could reasonably be expected to be ascertained, understood and regarded as relevant by a person skilled in the art.

### SUMMARY OF THE INVENTION

The inventors have discovered that thermoelectric devices, especially those also displaying a thermomagnetic property, may be applied to a metallurgical processing structure whose operation generates a magnetic field. The existence of a suitably oriented magnetic field in addition to the temperature gradient through the thermoelectric device provides an increase in the electrical energy generated over that when the magnetic field does not exist. The inventors hope to improve control of crust formation, and/or to enhance overall cell efficiency, by controlling and harvesting the heat energy lost from the metallurgical processing structure to create electricity.

Accordingly, in one aspect of the present invention there is provided a method for utilizing thermal energy from a surface of a metallurgical processing structure, the method including
based on the direction of the magnetic field generated by the operation of the processing vessel, positioning a thermoelectric device in the magnetic field; the thermoelectric device having at least one thermoelectric element having the property of greater electrical generation efficiency when appropriately aligned in a magnetic field; the thermoelectric device being in thermal communication with the surface of the vessel
establishing or maintaining a temperature difference between a first side and second side of the thermoelectric device and generating electrical energy from the temperature differential within the thermoelectric device; and
collecting the electrical energy generated by the thermoelectric device.

According to another aspect there is provided a method for increasing the electrical efficiency and controlling the thermal balance, of an processing vessel, the method including
providing a thermoelectric device having at least one thermoelectric element positioned between a first side and a second side of the thermoelectric device; the first side being positioned
   (a) adjacent to, and in thermal communication with, a heated surface of the pyrometallurgical vessel; the thermal communication being such that thermal energy is transferable from the surface to the first side by radiation, and
   (b) within a magnetic field generated by the operation of the processing vessel so that the magnetic field increases the efficiency of the thermoelectric device;
passing a first fluid between the surface and the first side such that thermal energy is transferable from the surface to the first side by convection
allowing the thermal energy transferred from the surface to the first side to conduct from the first side to the second side;
passing a second fluid over the second side to cool the second side of the thermoelectric element by convection and
collecting the electrical energy generated by the thermoelectric element

The processing structure may be an electrolytic cell having a magnetic field associated therewith. In the case of the electrolytic cell, the magnetic field is generated by the flow of electric current around the cell. Preferably, the electrolytic cell is for the production of aluminium. In these embodiments, the thermoelectric device is aligned in the magnetic field such that the electrical energy produced by the thermoelectric device is increased or maximized.

In accordance with the invention, the thermoelectric device may be retrofitted to an existing processing structure or it may be incorporated into a new structure.

In a further aspect of the present invention, there is provided an apparatus for the conversion of thermal energy from a surface of a pyrometallurgical vessel associated with a magnetic field to electrical energy, the device comprising
a thermoelectric device having at least one thermoelectric element capable of converting a temperature gradient into electrical energy whereby appropriate alignment in the magnetic field increases the ability of the thermoelectric device to generate electrical energy; and
a support structure engagable with the pyrometallugical vessel, the support structure being able to support the thermoelectric device in a fixed position in relative to the pyrometallurgical vessel and in the associated magnetic field so that a temperature differential exists between a first side and a second side of the thermoelectric device.

The thermoelectric device includes at least one thermoelectric element having a material displaying both the Seebeck effect (generation of an electric current by application a temperature difference) and the Nernst effect (generation of an electric current by the joint application of a temperature difference and a suitably-oriented magnetic field). That is, the thermoelectric device is also a thermomagnetic device.

The invention further defines a metallurgical processing structure and in particular an electrolysis cell having a thermoelectric device as described above aligned in a magnetic field generated by the processing structure and positioned adjacent to a surface of the processing structure for recovering and converting thermal energy to electrical energy.

As used herein, except where the context requires otherwise, the term “comprise” and variations of the term, such as “comprising”, “comprises” and “comprised”, are not intended to exclude further additives, components, integers or steps.

### BRIEF DESCRIPTION OF THE DRAWINGS

FIG. 1 is a perspective view of a schematic representing an embodiment of the thermoelectric device of the present invention.

FIG. 2 is a perspective view of the first side of the thermoelectric device showing fins and the thermoelectric elements in cut-away (normally hidden by the first side).

FIG. 3 is a perspective view of the first side of the thermoelectric device showing alternate fins and the thermoelectric elements in cut-away (normally hidden by the first side).

FIG. 4 is a perspective view of the second side of the thermoelectric device showing a cut-away of the optional outer boundary surface, and

FIG. 5 is a perspective view of the first side of the thermoelectric device showing the direction of alignment of the device with respect to a magnetic field.

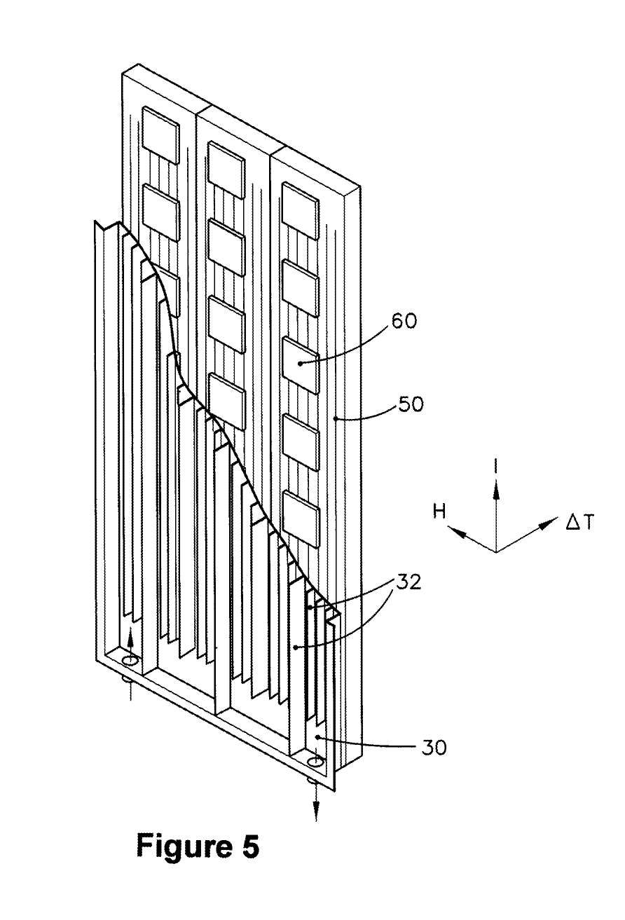

### DETAILED DESCRIPTION OF THE EMBODIMENTS

A preferred embodiment of the invention will now be described with reference to the above drawings.

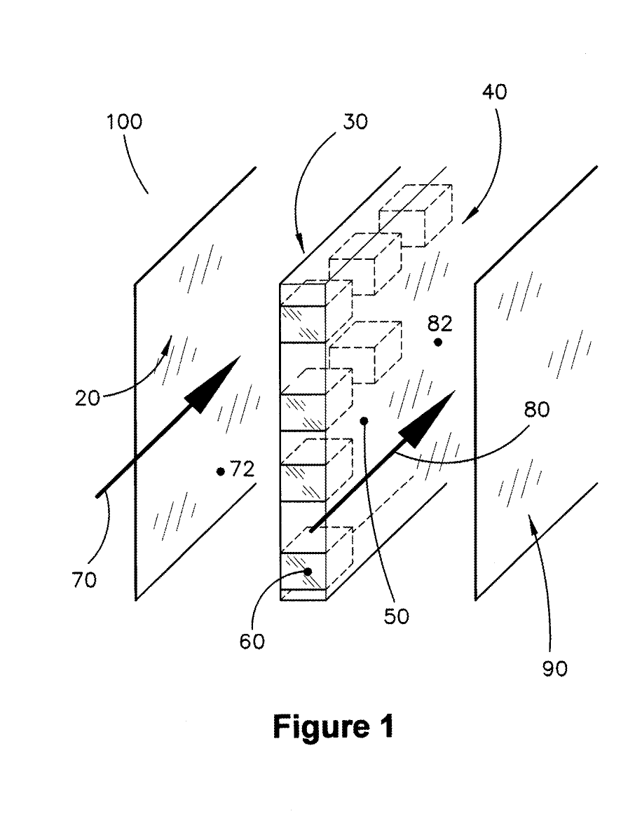

The apparatus 100 shown in FIG. 1 includes a thermoelectric device having a first side 30 and a second side 40, between which there is positioned body portion 50 and at least one thermoelectric element 60. The thermoelectric device is adapted to be positioned adjacent to, and in thermal communication with, a surface 20 of a processing structure from which thermal energy may be transferred by radiation and optionally by convection. The apparatus may further be provided with a support structure to maintain the body portion of the thermoelectric device a spaced distance from the radiating surface of the processing structure, the first side of the thermoelectric element or elements in the body portion facing towards the radiating surface of the processing structure. A first space 72 is created between the radiating surface of the processing structure. The spaced distance between the first side of the body portion and the surface of the processing vessel provides a passage for a first fluid which may optionally aid in convective heat transfer from the surface 20 of the processing structure.

The supporting structure may comprise a housing having side walls to support the body portion of the thermoelectric device a spaced distance from the radiating surface of the processing structure or vessel. The housing may be provided with fins which direct flow through the first space from an inlet to an outlet. The inlet and outlet to the first space is preferably provided through the side of the housing wall in the direction of fluid flow. The fins for directing fluid flow may be completely traverse the first space thus providing separate fluid flow chambers or may extend only partially across the first space to act as guide vanes for the fluid flow.

The housing for the thermoelectric device may further include an outer casing, the second side of the thermoelectric device and the outer casing defining a second space there between. A second fluid 80 may be passed over the second side, optionally through a second space 82 between the second side and an optional outer casing 90.

The first fluid and a second fluid pass through the first space and the second space, respectively. The first fluid is of a higher temperature than the second fluid.

The amount of heat energy transferred from the surface, Q, is the sum of the convective, Q_{c}, and radiative, Q_{R}, components. If a first fluid of initial temperature Tᵢₙ is passed between the surface and the first side over an area A to result in a final temperature Tₒᵤₜ, then Q_{c}=A.h.(Tₒᵤₜ−Tᵢₙ), where h is the heat transfer coefficient. If the temperature of the surface is Tₛ and the temperature of the first side is T₁ₛₜ, then Q_{R}=A.ε.(T₁ₛₜ⁴−Tₛ⁴), where E is proportional to the emissivity of the first side.

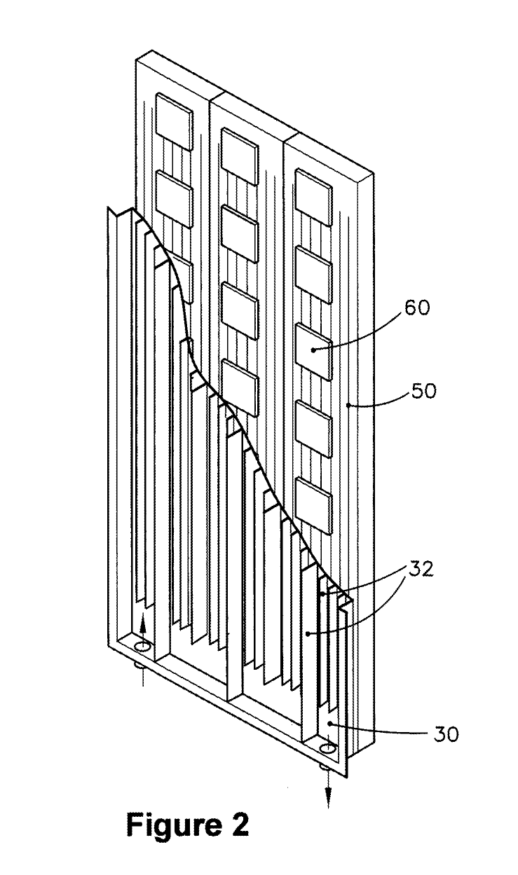

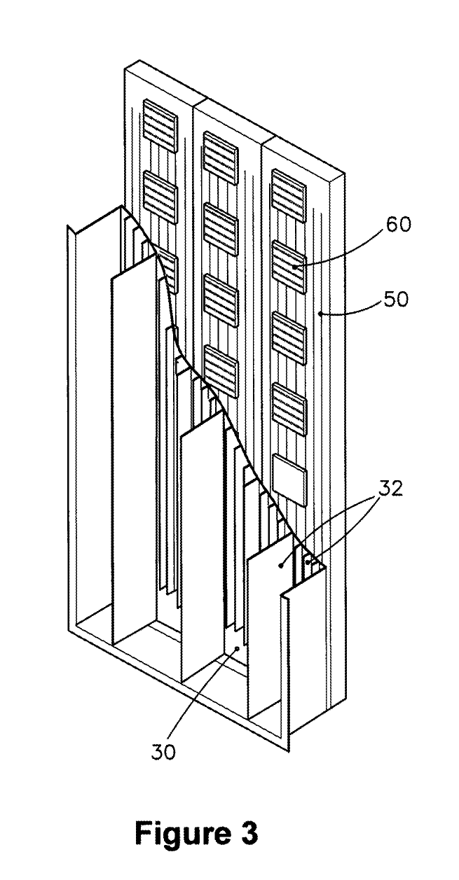

The material used to construct first side 30 and second side 40 is preferably thermally conductive to provide for a more even temperature distribution. To this end, a particularly suitable material is aluminium. The material of the first side may require treatment (coating, anodising, or other method) so as to adopt an emissivity approaching 1 so that Q_{R} absorbed approaches Q_{R} emitted by the surface. The first side may be of any profile; however a particularly preferred profile is one which allows Q_{c} absorbed to approach Q_{c} transferred from the surface without adversely affecting he radiative conduction to the first side. For instance, the first side may include fins 32 (FIGS. 2 and 3) to increase the surface area available for heat transfer from, and to avoid laminar flow of, the first fluid.

The material used to construct the body portion 50 is preferably an insulator to inhibit the flow of thermal energy through the material of the body portion per se and to increase the amount of thermal energy forced to be transferred through the thermoelectric elements. For instance, the body portion may be made from pre-formed ceramic compacts (alumina, magnesia, zirconia, etc) or other material which would impede the flow of heat and electricity through its matrix.

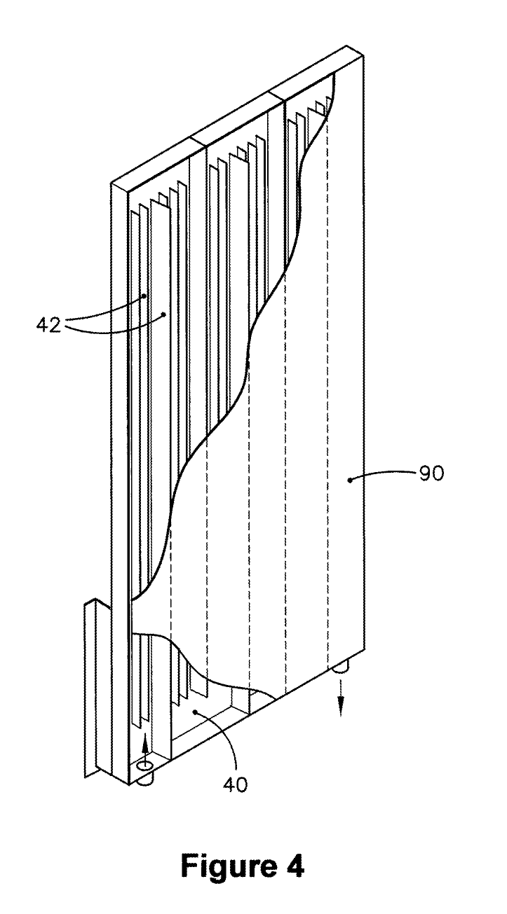

By controlling the type of fluid used as the first and second fluids, and their flow rate through the first and second spaces, it is possible to control (to a degree) the thermal energy being transferred from the processing structure. A greater degree of control may be provided by the incorporation of a heat exchanger type arrangement within the first and/or second spaces. For example, an internal cooling arrangement as described in PCT/AU2005/001617 may be employed (such as shown in FIG. 4). The controlled cooling of an external surface of the processing structure of the present invention is superior to that presently known in the art. That is, it provides a greater possible degree of cooling with tighter control.

In relation to an electrolytic cell, this enhanced control of the thermal balance within the cell is significant. Most importantly, the outside temperature of the shell of the electrolytic tank can be controlled so that the formation of the ledge/freeze lining can also be controlled. As an example, the fluid flow rates can be controlled in response to the outside temperature of the shell such that if the outside temperature drops the flow rates can also be slowed to result in a reduced transfer of thermal energy from the shell to the thermoelectric device. The flow rates could be controlled by any means known in the art, for instance, a valve or damper system.

The fluid can be gas or liquid. Preferably, the fluid is a gas as this is cheaper to install and safer to operate. For instance, the fluid may be air. The first fluid flowing through the first space will be of a greater temperature than the second fluid flowing through the second space. In the first space, the first fluid is heated by the surface of the processing structure convectively and transfers its thermal load to the first side convectively. Heat is also passed to the first side from the surface through radiation transfer. The first side may include a series of fins 32 or the like that project into the first space to increase the thermal transfer. In the second space, the second fluid is used to remove heat from the second side. The second fluid is preferably at ambient temperatures, but may be cooled. The second side may include a series of fins 42 (FIG. 4) or the like that project into the second space to increase the thermal transfer. The fluids may be propelled through the spaces by any means known in the art. For instance, a fan or blower may be used, and may also be powered by electrical energy produced by the thermoelectric device.

The thermoelectric element 60 may be made from any material known in the art to demonstrate the Seebeck or Nernst effects at high temperatures. Typically, thermoelectric materials are semi-conducting metals or semi-metals. In several common manifestations, the thermoelectric material includes bismuth, lead or gallium compounds which may include lead telluride, lead selenide, bismuth antimony, gallium arsenide and gallium phosphide. The main requirement is that the material be able to operate at temperatures approximately between 100° C. and 500° C.

The wafers are aligned in an insulating support panel, body portion 50 with the wafers containing an array of individual thermoelectric elements alternating between a p and n type material electrically connected through the support panel by printed circuits or the like. The matrix of wafers is covered on both the hot and cool sides by layer of diffuser material such as aluminium which assists in providing an even temperature across the heat exchanger and particularly avoids hots spots forming. The layer of diffuser material may be provided with fins or baffles which are preferably arranged in a circuitous path to allow a fluid to flow through the shell side of the device.

Similarly the cool side of the thermomagnetic device (ie the side facing away from the cell walls) is provided with an aluminium diffuser sheet and heat exchange channels through which a cooling fluid is passed.

The heat radiating from the surface of the vessel and the temperature difference between the fluids flowing through the heat exchanger channels provides the driving force for the thermoelectric device.

To enhance the thermoelectric effect, the device which consists of a thermomagnetic as well as a thermoelectric material is placed in a magnetic field so that the direction of heat flow, the direction of current flow and the magnetic field are orthogonally aligned consistent with a right hand rule. If the device is aligned so that direction of magnetic field is in the plane of the matrix of wafers across the panel and the heat flow from the vessel is away from the vessel wall into the hot face side of the device then the current up the panel. This current is enhanced when the magnetic field is aligned as described above when compared with the magnetic field in another direction due to the properties of the thermomagnetic material.

Thus a thermomagnetic device may be retro fitted to an existing metallurgical processing structure such as an electrolysis cell which generated a magnetic field through the actions of the process being performed in the structure or it may be incorporated into the design of a new facility.

It will be understood that the invention disclosed and defined in this specification extends to all alternative combinations of two or more of the individual features mentioned or evident from the text or drawings. All of these different combinations constitute various alternative aspects of the invention.

1-24. (canceled)

25. A method for harvesting heat energy from a surface of a metallurgical vessel, the method including the steps of
operating a metallurgical process in the metallurgical vessel whereby the operation of the metallurgical process generates a magnetic field
based on the direction of the magnetic field generated by the operation of the metallurgical process, positioning a thermoelectric device in the magnetic field, the thermoelectric device operating in the temperature range of 100 to 500° C. and having at least one thermoelectric element having the property of greater electrical generation efficiency when appropriately aligned in a magnetic field; the thermoelectric device being in thermal communication with the outside surface of the vessel
maintaining a temperature difference between a first side and second side of the thermoelectric device and generating electrical energy from the temperature differential through the thickness of the thermoelectric device; and
collecting the electrical energy generated by the thermoelectric device.

26. A method for increasing the electrical efficiency and controlling the thermal balance, of a processing vessel, the method including
providing a thermoelectric device having at least one thermoelectric element positioned between a first side and a second side of the thermoelectric device; the first side being positioned
(a) adjacent to, and in thermal communication with, a surface of the pyrometallurgical vessel; the thermal communication being such that thermal energy is transferable from the surface to the first side by radiation, and
(b) within a magnetic field generated by the operation of the processing vessel so that the magnetic field increases the efficiency of the thermoelectric device;
passing a first fluid between the surface and the first side such that thermal energy is transferable from the surface to the first side by convection
allowing the thermal energy transferred from the surface to the first side to conduct from the first side to the second side; and
collecting the electrical energy generated by the thermoelectric element

27. The method of claim 25 or 26 whereby adjustment of the first fluid provides for control of the thermal balance of the electrolysis cell.

28. The method of claim 25 or 26 wherein the thermoelectric device is aligned in the Magnetic field such that the electrical energy produced by the thermoelectric device is increased.

29. The method of claim 25 or 26 wherein the pyrometallurgical vessel is an electrolytic cell.

30. The method of claim 25 or 26 wherein the electrolytic cell is for the production of aluminium.

31. An apparatus for the conversion of thermal energy from a surface of a pyrometallurgical vessel, the operating of the pyrometallurgical vessel generating a magnetic field to electrical energy, the device comprising
a thermoelectric device having at least one thermoelectric element capable of operating in the temperature range of 100 to 500° C. to convert a temperature differential across that element into electrical energy whereby appropriate alignment in the magnetic field increases the ability of the thermoelectric device to generate electrical energy; and
a support structure engagable with the pyrometallugical vessel, the support structure being able to support the thermoelectric device in a fixed position relative to a surface of the pyrometallurgical vessel and in the magnetic field generated by the operation of the pyrometallurgical vessel so that a temperature differential exists between a first side and a second side of the thermoelectric device.

32. The apparatus of claim 31 wherein the thermoelectric device is aligned in the magnetic field associated with the pyrometallurgical vessel to generate greater electrical energy from the device than would be generated in the absence of the magnetic field.

33. The apparatus of claim 31 wherein the support structure maintains the first side of the thermoelectric device in a position to receive thermal energy from the metallurgical vessel surface by radiation and convection, the first side and the surface defining a first space there between.

34. The apparatus of claim 31 wherein the support structure comprises a housing having side walls to support the thermoelectric device a spaced distance from the radiating surface of the pyrometallurgical vessel.

35. The apparatus of claim 33 wherein the thermoelectric device further comprises a body portion positioned between the first side and the second side, and having therein at least one thermoelectric element for generating electrical energy from a temperature difference between the first side and the second side.

36. The apparatus of claim 35 wherein the spaced distance between the first side of the thermoelectric device and the surface of the pyrometallurgical vessel provides a first space for the passage for a first fluid.

37. The apparatus of claim 35 or 36 wherein fins are provided in the first space.

38. The apparatus of claim 37 wherein the fins for directing fluid flow completely traverse the first space thus providing separate fluid flow chambers.

39. The apparatus of claim 37 wherein the fins for directing fluid flow extend only partially across the first space to act as guide vanes for the fluid flow or heat convention.

40. The apparatus of claim 35 wherein the housing for the thermoelectric device further comprises an outer wall, the second side of the thermoelectric device and the outer wall defining a second space there between through which a second fluid passes.

41. The apparatus of claim 35 further including an outer wall, the second side and the outer wall defining a second space there between.

42. The apparatus of claim 41 wherein the first space and the second space being for the passage of a first fluid and a second fluid, respectively.

43. The apparatus of claim 31 wherein the first side and second side are made from a conducting material.

44. The apparatus of claim 31 wherein the thermoelectric device comprises a body portion to retain the thermoelectric element or elements, the body portion being made from an insulating material.
